(19) United States
(12) Patent Application Publication
(10) Pub. No.: US 2024/0222139 A1
(43) Pub. Date: Jul. 4, 2024

(54) MICROELECTRONIC PACKAGE STRUCTURES WITH SOLDER JOINT ASSEMBLIES HAVING ROUGHENED BUMP STRUCTURES

(71) Applicant: Intel Corporation, Santa Clara, CA (US)

(72) Inventors: Suddhasattwa Nad, Chandler, AZ (US); Brandon Marin, Gilbert, AZ (US); Gang Duan, Chandler, AZ (US); Jeremy Ecton, Gilbert, AZ (US); Srinivas Pietambaram, Chandler, AZ (US)

(73) Assignee: Intel Corporation, Santa Clara, CA (US)

(21) Appl. No.: 18/090,879

(22) Filed: Dec. 29, 2022

(51) Int. Cl. H01L 21/48; H01L 23/00; H01L 23/495; H01L 25/065

(52) U.S. Cl. CPC H01L 21/4842; H01L 23/49548; H01L 23/49575; H01L 23/49582; H01L 24/16; H01L 25/0655; H01L 2224/16258

(57) ABSTRACT

Microelectronic integrated circuit package structures include a solder joint structure having a first portion on a die and a second portion on a substrate. The first portion comprises a first metal. An inner portion of the second portion comprises a second metal, and an outer portion of the second portion comprises an intermetallic compound (IMC) of the first and second metals.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

In many integrated circuit packages, one or more semiconductor dies are mechanically and electrically coupled to an underlying package substrate. Frequently, the coupling of a die to an underlying substrate is achieved by aligning and connecting metal pads and/or bumps fabricated on a surface of the die with corresponding pads and/or bumps on a facing surface of an underlying substrate (e.g., a separate die or a package substrate). As integrated circuits and their associated packages continue to decrease in size, the bumps and/or pads associated with interconnects also need to decrease in size.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1C are cross-sectional views of IC package structures comprising solder joints with nano-roughened bump structures, in accordance with some embodiments.

FIGS. 2A-2H illustrate cross-sectional views of structures formed during the fabrication of IC package structures comprising solder joints with nano-roughened bump structures, in accordance with some embodiments.

FIG. 3 illustrates a flow chart of a process for the fabrication of IC package structures having comprising solder joints with nano-roughened bump structures, in accordance with some embodiments.

FIG. 4 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with solder joint sorting and minimization of conductive bump pitch. Coupling modular dies is required to meet high bandwidth die to die communication requirements. There is a need for a significant decrease in low bump thickness variation (BTV) at finer bump (pad) pitches while reducing manufacturing costs.

The roughened copper bump structures provide surfaces for solder wicking along portions of solder joint structures described herein. The embodiments greatly improve BTV control at smaller bump pitches. Improved affordability with lower costs per unit is achieved, as well as faster processing time with more efficient processing flows.

Embodiments herein describe the fabrication of solder joint bumps which provide a reduced pitch between adjacent bumps and a reduced degree of solder shorts. The package structures herein enable a decrease in manufacturing cost process window, since a reduced amount of solder is required to fabricate the solder joints of the embodiments described herein. For example, a solder joints comprising nano-roughened conductive pads and subsequent intermetallic compound formation on roughened portions of conductive pads described herein may include solder joint structures comprising conductive pads on a substrate. The conductive pads may comprise an inner portion and an outer portion, where the inner portion comprises a metal that has undergone a nano-roughening process. The nano-roughening process provides a surface onto which an intermetallic compound (IMC) may form. The IMC may comprise materials from both the conductive substrate pad and a die pad which is attached to the conductive substrate pad during a die attach process.

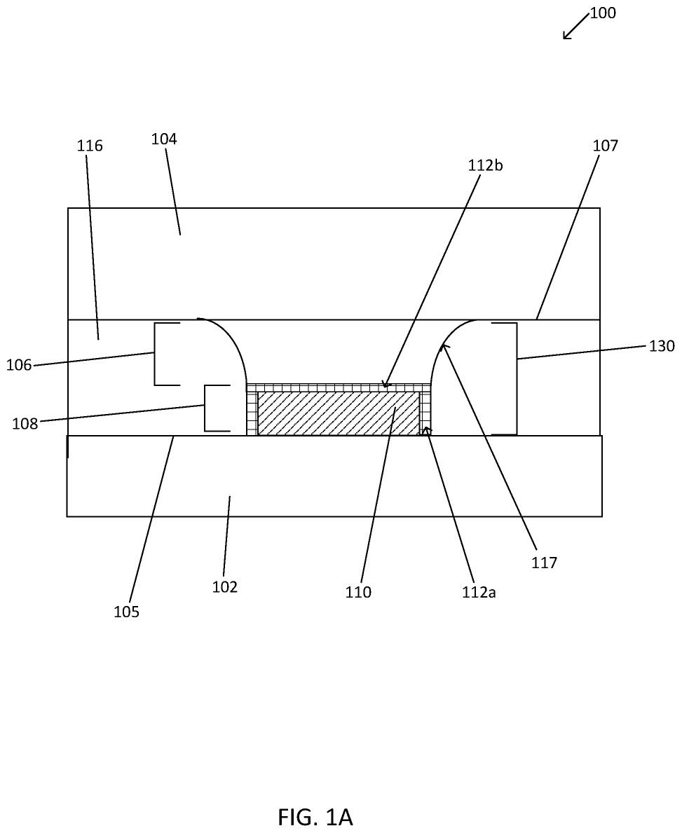

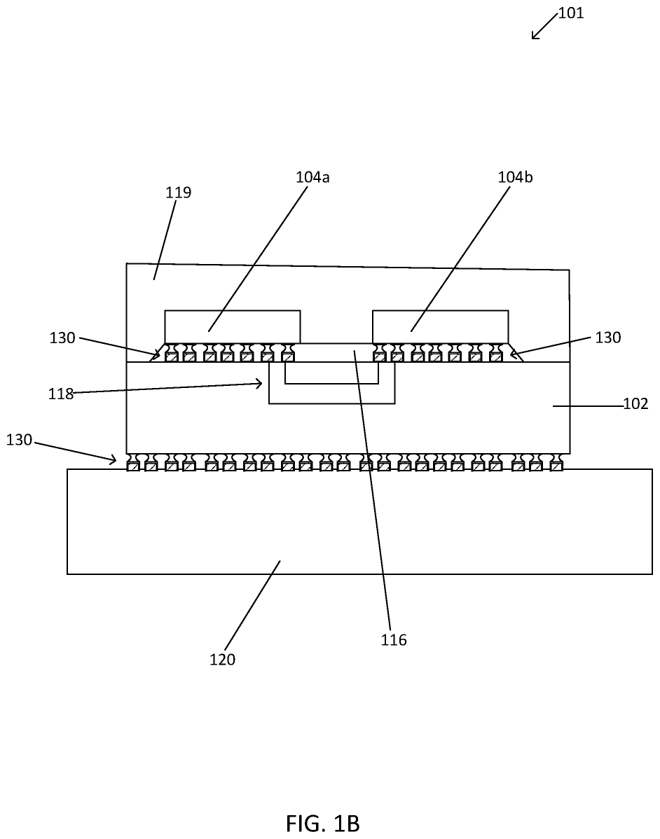

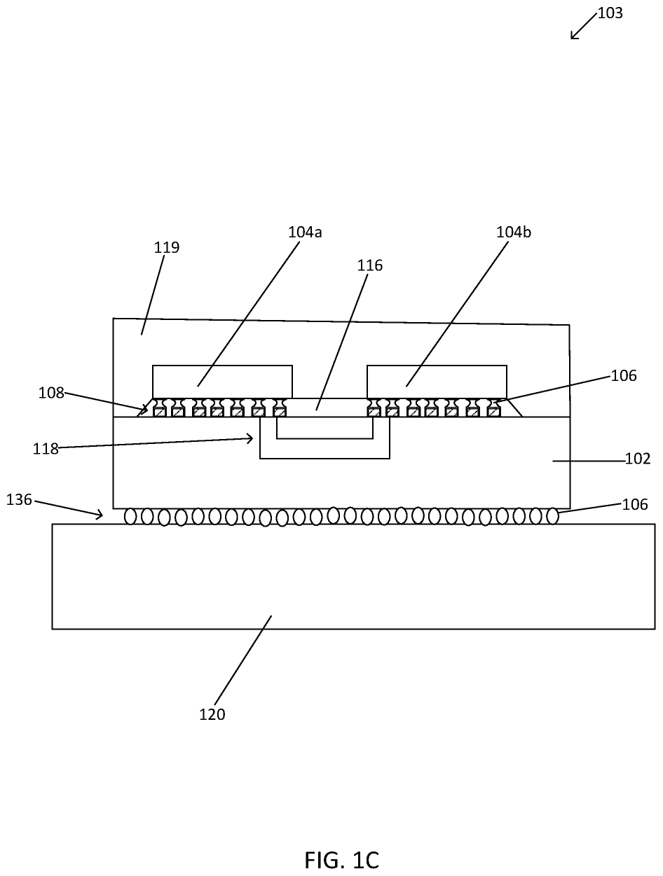

FIGS. 1A-1C illustrate embodiments of package structures to be utilized for substrates of packaged microelectronic devices, in accordance with some embodiments. The solder joint structures comprising nano-roughened conductive bumps include a first portion comprising a first metal on a die, and a second portion comprising a second metal on the substrate. The second portion comprises an inner portion and an outer portion, the inner portion comprising the second metal and the outer portion comprising an intermetallic compound (IMC) of the first and second metals. The package structure(s) herein are to be used as a portion of a microelectronic device. The joint structures fabricated according to the described embodiments enable fine pitches between adjacent die and thus allow for connecting modular dies to meet high bandwidth communication connection needs.

FIG. 1A is a cross-sectional view of a portion of an integrated circuit (IC) package structure 100, in accordance with some embodiments. In the embodiment depicted in FIG. 1A, IC package substrate structure 100 includes a substrate 102. The substrate 102 may comprise silicon or glass or may comprise an organic substrate in some embodiments. The substrate 102 may be any appropriate structure, such as a substrate core with at least one dielectric material such as build up films and/or solder resist layers (not shown). The substrate 102 may further include conductive interconnect structures such as conductive traces and conductive vias extending within and through the substrate 102. The conductive routing may comprise any appropriate conductive material, including, but not limited to metals, such as copper, silver, nickel, gold, and aluminum, alloys thereof, and the like. In an embodiment, the substrate 102 may comprise a joint structure 130 on a surface 105 of the substrate 102, wherein the joint structure 130 is between the substrate 102 and a die 104. In an embodiment, one or more dies 104 may be coupled to the substrate 102.

In an embodiment, the joint structure 130 may comprise a solder joint structure 130 which may electrically and physically couple the die 104 to the substrate 102. In an embodiment, the joint structure 130 may comprise a first portion 106 and a second portion 108. The first portion 106 of the joint structure 130 may comprise solder materials in an embodiment, such as, but not limited to tin, silver, copper, gold, bismuth, zinc and the like. In an embodiment, the first portion 106 may comprise a first metal(s). The first portion 106 may be on a surface 107 of the die 104. The first portion 106 may comprise a substantially concave cross-sectional profile 117 and the second portion 108 may comprise a substantially rectangular cross-sectional profile, in an embodiment. The first portion 106 may be directly on the second portion 108 of the joint structure 130.

In an embodiment, the second portion 108 of the solder joint 130 may comprise an inner portion 110 and an outer portions 112a, 112b. Outer portions 112a may be on sidewalls of the inner portion 110, and outer portion 112b may be on a top portion of the inner portion 110. In an embodiment, the inner portion 110 may comprise a second metal, and may comprise a conductive compound such as copper or copper alloys. In an embodiment, the outer portions 112a, 112b may comprise an (IMC) of the first and second metals of the first portion 106 and the inner portion 110 respectively. In an embodiment, the outer portion 112b may be between the first portion 106 and the inner portion 110. In an embodiment, the outer portions 112a may be between a dielectric material 116 and the inner portion 110. In an embodiment, the dielectric material 116 may comprise an underfill material, such as an epoxy resin material for example. In an embodiment, the outer portions 112a, 112b of the second portion 108 may comprise a lateral width of between about 5 percent to about 30 percent of a lateral width of the inner portion 110.

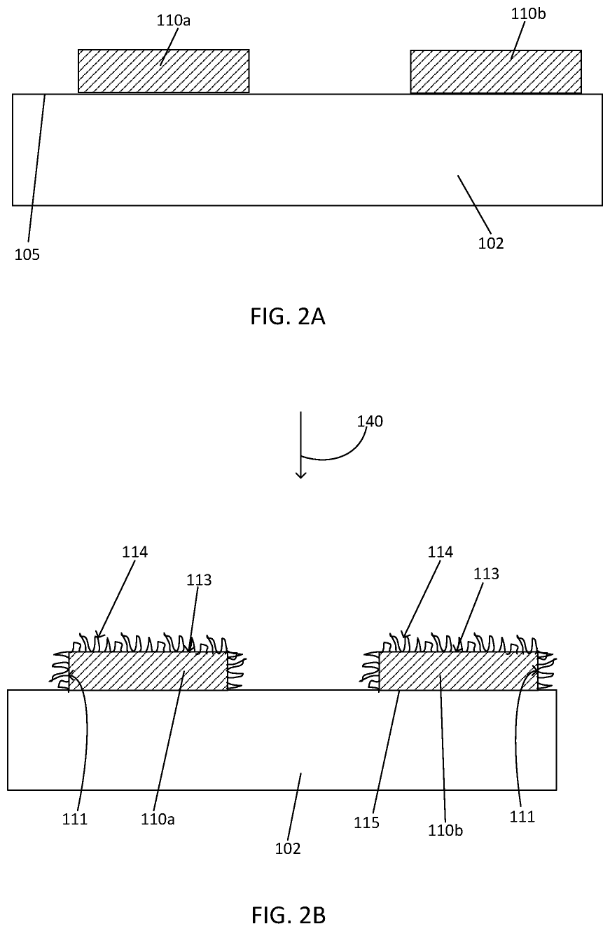

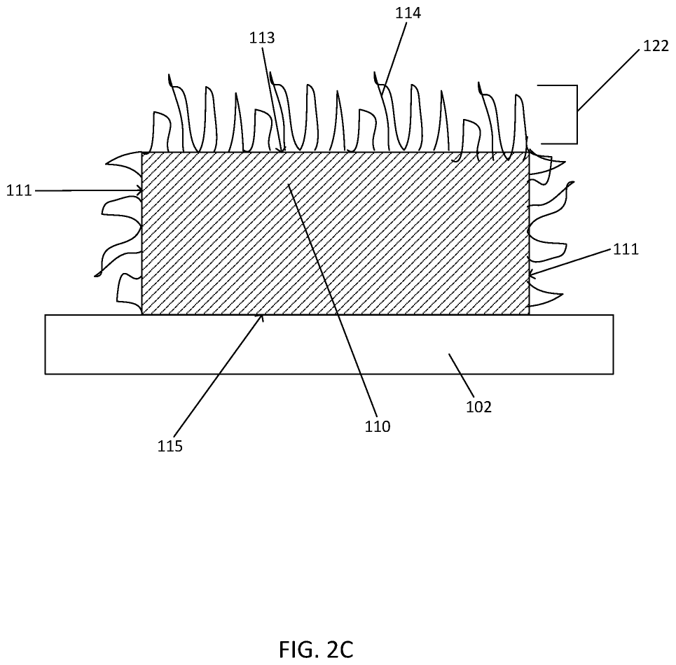

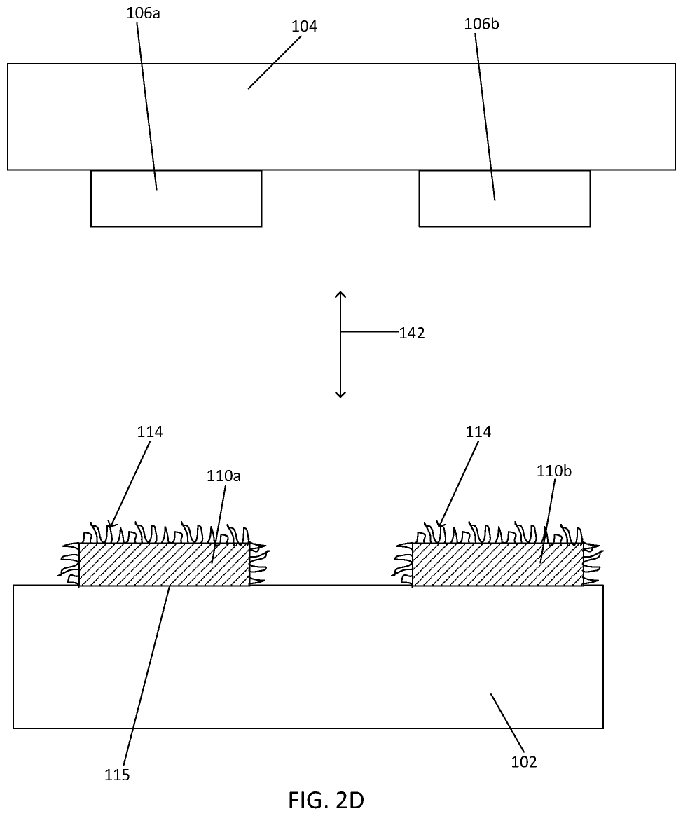

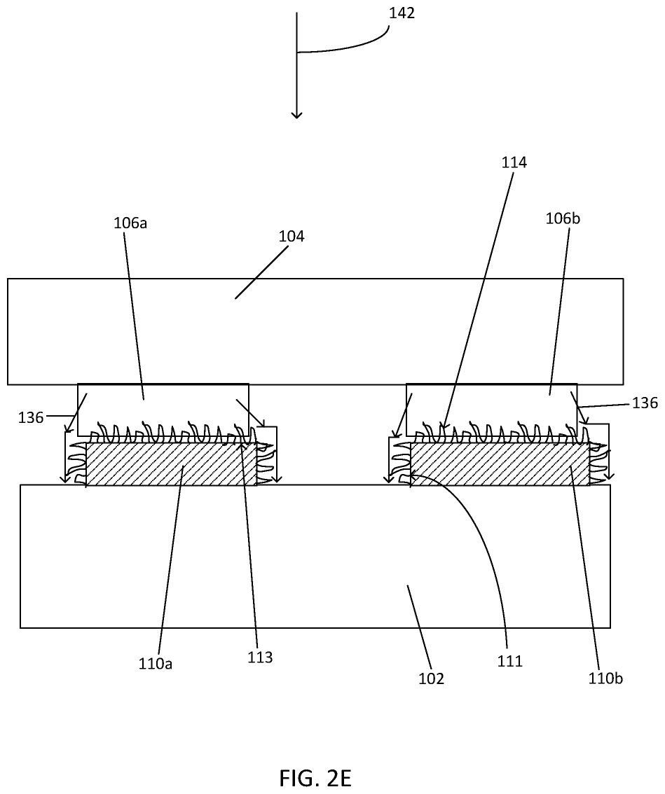

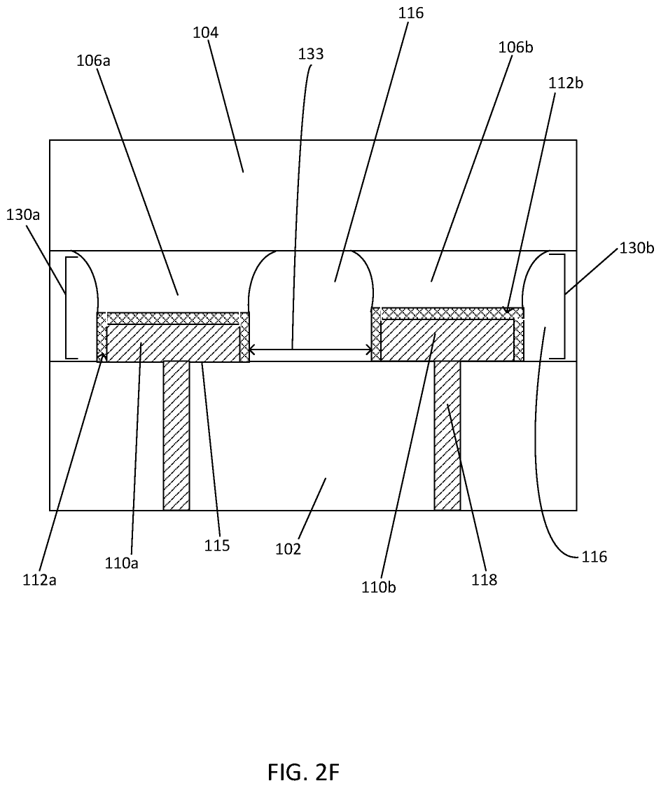

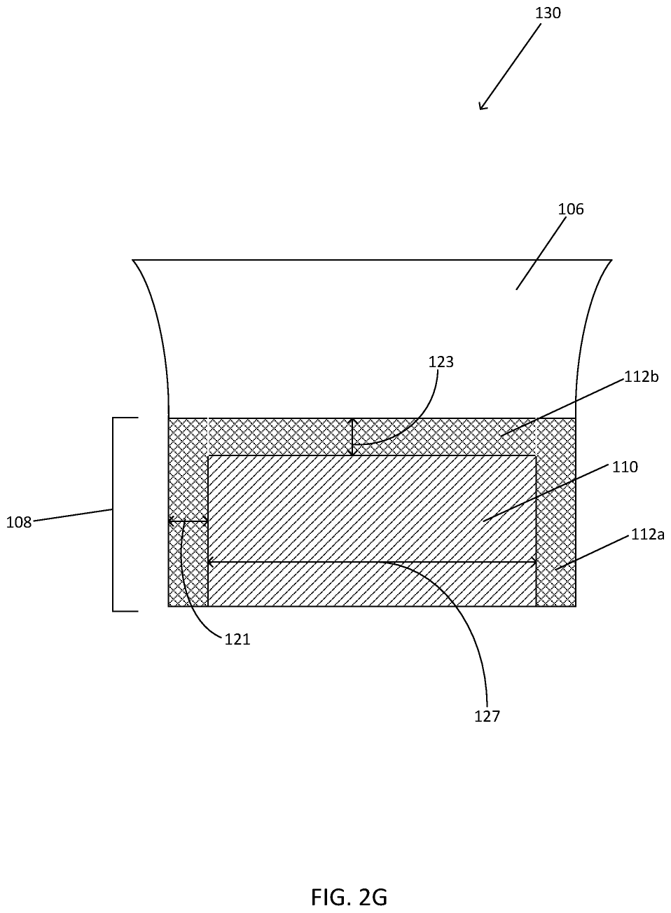

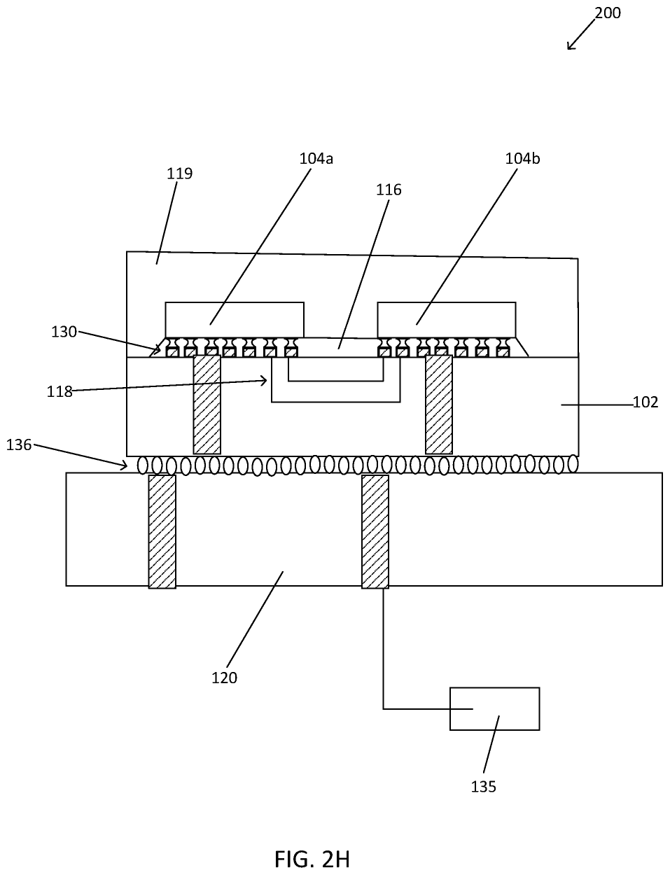

FIG. 1B is a cross-sectional view of an IC package structure 101, in accordance with some embodiments. IC Package structure 101 includes a plurality of joint structures 130 (similar to the joint structures of FIG. 1A) coupling first and second dies 104a, 104b to a substrate 102. An underfill material 116 surrounds the plurality of joint structures 130. The plurality of joint structures 130 coupling first and second dies 104a, 104b to the substrate 102 may comprise first level interconnect structures. The substrate 102 may be coupled to a board 120, such as a printed circuit (PC) board 120. In an embodiment, the board 120 may be coupled to the substrate 102 by the plurality of joint structures 130, which may comprise second level interconnect structures. In an embodiment, a distance between adjacent individual joint structures 130 may be about 25 microns or less (as shown in FIG. 2F, for example). In an embodiment, a bridge structure 118 may couple the first and second dies 104a, 104b, and a mold material 119 may surround the dies 104a, 104b over the substrate 102.

FIG. 1C is a cross-sectional view of an IC package structure 103, in accordance with some embodiments. IC Package structure 103 includes a plurality of joint structures 1369 (similar to the joint structures of FIG. 1A) coupling first and second dies 104a, 104b to a substrate 102. An underfill material 116 surrounds the plurality of joint structures 1369 coupling first and second dies 104a, 104b to the substrate 102, which may comprise first level interconnect structures. The substrate 102 may be coupled to a board 120, such as a (PC) board 120. In an embodiment, the board 120 may be coupled to the substrate 102 by a plurality of solder ball structures 1369, which may comprise second level interconnect structures. In an embodiment, a bridge structure 118 may couple the first and second dies 104a, 104b, and a mold material 119 may surround the dies 104a, 104b over the substrate 102. The solder joints 1360 of the embodiments herein minimize solder joint shorts as well as reducing r(BTV) due to minimizing bump pitch.

FIGS. 2A-2H illustrate embodiments of forming an IC package structure (such as the IC package structures of FIGS. 1A-1C). FIG. 2A depicts a cross-sectional view of a portion of a portion of an IC package structure according to some embodiments. As shown, a substrate 102 may be provided. Substrate 102 may include conductive material with dielectric material interspersed within substrate 102. Substrate 102 may additionally include integrated circuitry fabricated according to any suitable microelectronic technology such as complementary metal oxide semiconductor (CMOS), SiGe, III-V or III-N HEMTs, etc.) techniques or others. For example, substrate 102 may include any number of active or passive devices. In some embodiments, substrate 102 may be an interposer or a PC board.

In some embodiments, the substrate 102 may comprise a glass or a silicon substrate 102, or an organic substrate. In an embodiment, the substrate 102 may comprise a silicon or glass interposer 102, a substrate package or a substrate patch. Adjacent conductive pads 110a, 110b, may comprise copper pads, for example, and may be on a surface 105 of the substrate 102. In an embodiment, the conductive pads 110a, 110b may comprise copper or alloys thereof and may comprise a thickness of up to about 100 microns.

A nano-roughening process 140 may be employed to form protrusions 114 from surfaces 111, 113 of the conductive pads 110a, 110b (FIG. 2B). The process 140 may comprise a series of selective etching processes wherein portions of the conductive pads 110a, 110b may be selectively removed in order to produce protrusions 114 extending above the top surface 113 and extending from sidewalls 111 of the conductive pads 110a, 110b, in an embodiment. In an embodiment, the protrusions 114 may comprise a root mean square roughness of less than or equal to about 100 nm. A bottom surface 115 of the conductive pad 110 is substantially free of the nano-roughened surface, since it is not exposed during the nano-roughening process 140 and is directly on the substrate 102.

FIG. 2C is a more detailed view of the nano-roughened conductive pad 110, wherein protrusions 114 extending from the sidewalls 111 and top surface 113 of the conductive pad 110 comprises a roughness 122. The degree of roughness 122 may be optimized for the particular application by varying the parameters of the roughening process 140. An attachment process 142 is depicted in FIGS. 2D-2E. In FIG. 2D, a die 104 comprising first and second die pads 106a, 106b is placed on the conductive pads 110a, 110b of the substrate 102. The attachment process 142 may be optimized for a particular application, but in some embodiments comprises a temperature of below about 300 degrees Celsius for a given time. The die pads 106a, 106b are aligned and mated with the conductive pads 110a, 110b of the substrate 102. In an embodiment, the die pads 104a, 104b may comprise solder materials, such as one or more of tin, silver gold, copper, bismuth or zinc. During the attachment process 142, the materials of the die pads 106a, 106b, such as the solder materials, begin to wick 136 onto the nano-roughened sidewalls 111 and top surface 113 of the conductive substrate pads 110a, 110b.

FIG. 2F depicts the formation of adjacent solder joints 130a, 130b between the die 104 and the substrate 102 subsequent to the application of the attachment process 142. IMC's 112a, 112b form on the nano-roughened sidewalls and top surfaces of the conductive pads 110a, 110b. In an embodiment, the IMC's 112a, 112b are not formed on the bottom surface 115 of the conductive pads 110a, 110b. The IMC's 112a, 112b may comprise solder materials and copper, for example, and may comprise a microstructure characteristic of the IMC formed from the die pad 106 and substrate pad 110 materials. By forming an intermetallic compound (IMC) on sidewalls 112a and on top surfaces 112b of the substrate conductive pads 110, a distance 133 between the first solder joint 130a and the second solder joint 130b solder is minimized. In an embodiment, the distance 133 may be about 25 microns or less. The embodiments of the solder joints presented herein utilize a reduced amount of solder material, thus greatly reducing manufacturing costs.

Dielectric material 116 may be adjacent the sidewall IMC's 112a. In an embodiment, the dielectric material 116 may comprise an underfill material. In an embodiment, the IMC 112b may be between the die pad 106 and the conductive pad 110. In an embodiment, the solder joints 130a, 130b may be coupled to one or more conductive traces 118 within the substrate 102. FIG. 2G depicts an individual solder joint 130 wherein the die pad 106 comprises a first portion 106 of the solder joint 130 and is on a second portion 108 of the solder joint 130. In an embodiment, the second portion 108 comprises outer portions 112a, 112b and an inner portion 110. In an embodiment, a height 123 of the IMC 112b and a lateral width 121 of the IMC 112a are about 5 percent to about 30 percent of a lateral width 127 of the inner portion 110. In an embodiment, the outer portions 112a, 112b comprise a liner that surrounds the inner portion 110 above the substrate.

As shown in FIG. 2H, IC package structure 200 includes a plurality of joint structures 130 (similar to the joint structures of FIG. 2F) coupling first and second dies 104a, 104b to a substrate 102. An underfill material 116 surrounds the plurality of joint structures 130. The plurality of joint structures 130 coupling first and second dies 104a, 104b to the substrate 102 may comprise first level interconnect structures. The substrate 102 may be coupled to a board 120, such as a printed circuit (PC) board 120. In an embodiment, the board 120 may be coupled to the substrate 102 by the plurality of solder balls 136, which may comprise second level interconnect structures.

As used herein, the term ball interconnect structures indicate any structure or conductive element for coupling to an outside die or other device. In an embodiment, ball interconnect structures 136 include a solder structure. For example, ball interconnect structures 136 may be solder balls. As used herein, the term solder balls indicate an interconnect structure prior to or after reflow. Ball interconnect structures 136 may include one or more of silver, tin, or copper, or combinations or alloys thereof. In an embodiment, a bridge structure 118 may couple the first and second dies 104a, 104b, and a mold material 119 may surround the dies 104a, 104b over the substrate 102.

The first and second dies 104a, 104b may be any appropriate die/device, including, but not limited to, a microprocessor, a chipset, a graphics device, a wireless device, a memory device, an application specific integrated circuit, a transceiver device, an input/output device, combinations thereof, stacks thereof, or the like. The dies 104a, 104b may be electrically coupled to a power supply 135, which may comprise any suitable power supply as known in the art, via IC package structure 200, in an embodiment.

Discussion now turns to operations for assembling and/or fabricating the discussed structures.

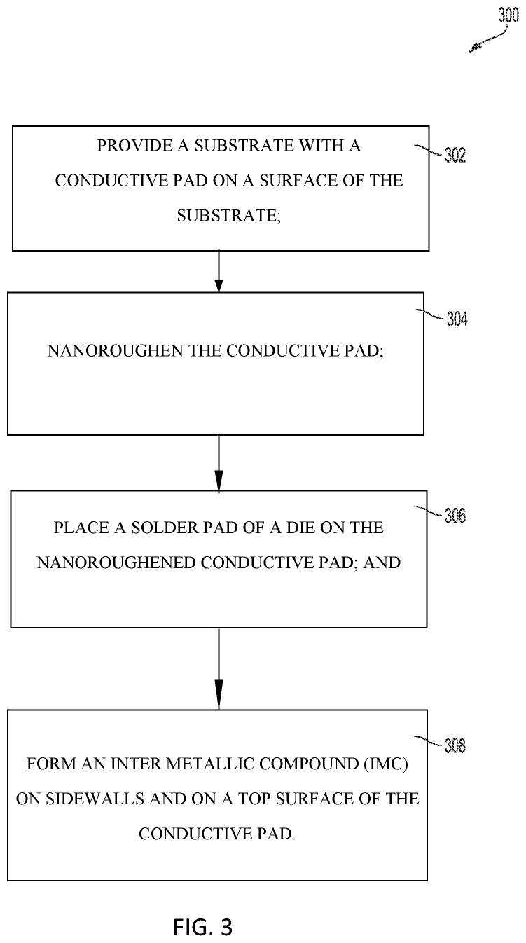

FIG. 3A is a flow chart of a process 300 of fabricating a microelectronic IC package structure according to some embodiments. For example, process 300 may be used to fabricate any of the microelectronic IC package structures of FIGS. 2A-2H.

As set forth in block 302, a substrate is provided with a conductive pad on a surface thereof. The substrate may comprise any suitable material, such as a glass or a silicon material, or may comprise an organic substrate. The substrate may further include one or more substrate pads such as conductive substrate pads. The substrate may include conductive material with dielectric material interspersed within the substrate. The substrate may additionally include integrated circuitry fabricated according to any suitable microelectronic technology such as complementary metal oxide semiconductor (CMOS), SiGe, III-V or III-N HEMTs, etc.) techniques or others. For example, the substrate may include any number of active or passive devices. In some embodiments, the substrate may be an interposer or a PC board. In an embodiment, one or more conductive pads may be on a surface of the substrate. The one or more conductive pads may comprise a conductive material such as copper material or copper alloys, in an embodiment. In an embodiment, the substrate may be coupled to a board, such as a printed circuit (PC) board, for example.

As set forth in block 304, the conductive pad may be nano-roughened. In an embodiment, a roughening process may be employed wherein exposed surfaces and sidewalls of the conductive pads on the surface of the substrate are nano-roughened using one or more surface treatments. For example, such surface treatments may include at least one of sequential bimetallic deposition and chemical etching, or sequential copper oxidation and reduction. In such examples, the nano-roughened surfaces enable subsequent wicking of solder material from solder die pads onto the conductive substrate pads and formation of an intermetallic compound on the top surface and sidewalls of the conductive pads. In an embodiment, the nano-roughened surface includes random areas on the surface of the conductive pads that comprise adjacent peaks and valleys. In an embodiment, the nano-roughened surfaces (top and sidewall surfaces) comprise a root mean square roughness of less than or equal to about 100 nm. In an embodiment, a surface of the conductive pad directly on the substrate is not substantially roughened during the roughening process.

As set forth in block 306, a solder pad of a die may be placed on the nano-roughened conductive pad. The solder pad may comprise any suitable solder material, such as tin, silver bismuth, zinc or copper. The die may comprise any suitable die, such as a microprocessor, a chipset, a graphics device, a wireless device, a memory device, an application specific integrated circuit, a transceiver device, an input/output device, combinations thereof, stacks thereof, or the like. A die attach process may be employed to place the solder pad of the die onto the nano-roughened conductive pad of the substrate. In an embodiment, the die attach process may comprise a temperature of below about 300 degrees Celsius and may comprise an amount of time at temperature (or at a series of different temperatures) dependent upon the particular application.

As set forth in block 308, an inter metallic compound (IMC) may be formed on sidewalls and on a top surface of the conductive pad. In an embodiment, the IMC may be any IMC that may be formed between the materials of the solder die pad and the materials of the conductive substrate pad. In an embodiment, the IMC may comprise any intermetallic compound as may be described in a phase diagram for the various materials of the IMC. In an embodiment, the IMC may comprise a microstructure that may be identified by a scanning electron microscope (SEM), where the microstructure is dependent upon the particular bonding process utilized as well as the particular materials utilized for a solder joint formation between the die and the substrate.

In an embodiment, the IMC may be formed during a bonding process, such as a die attach process. During the bonding process, a portion of the solder from the solder die pad may wick (i.e. the solder may flow away from the solder pad and onto the exposed surfaces of the conductive pad on the substrate) onto the exposed nano-roughened surfaces of the conductive substrate pad. In an embodiment, a bottom surface (i.e. the surface of the conductive pad on the substrate) may be free of the IMC. In an embodiment, an inner portion of the conductive pad may be free of the IMC. In an embodiment, a lateral width of the IMC may be from about 10 percent to about 20 percent of a thickness of the inner portion of the conductive pad. In an embodiment, a lateral width of the IMC may be from about 2 percent to about 30 percent of a thickness of the inner portion of the conductive pad.

In an embodiment, a thickness of the IMC may be between about 0.5 nm and 50 microns. Solder wicking may be formed on the sidewalls of the substrate pad and between the die solder pad and the conductive substrate pad. The wicking may occur during solder joint formation, wherein a portion of the solder material flows onto the sidewalls and forms an IMC on the sidewalls and in between the copper and solder. In an embodiment, a bottom surface of the copper die pad is free of the IMC. In an embodiment, due to the wicking, the conductive substrate pad portion of the solder joint comprising the IMC may comprise a rectangular cross-sectional profile, and the solder die pad portion of the solder joint comprises a concave cross-sectional profile.

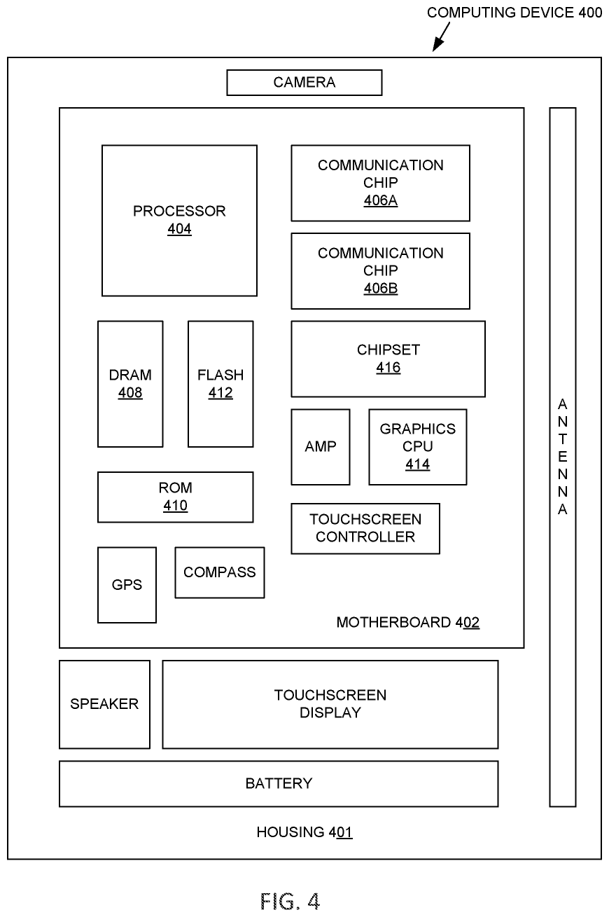

FIG. 4 illustrates an electronic or computing device 400 in accordance with one or more implementations of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a package substrate, a device, and a solder joint between the package structure and the device. The solder joint comprises a first portion comprising a first metal on the device and a second portion on the first portion. The second portion comprises an inner portion comprising a second metal and an outer portion at least partially surrounding the inner portion, the outer portion comprising an intermetallic compound (IMC) of the first and second metals.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-4. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein a first example is an apparatus, comprising a package substrate, a device, a solder feature comprising a first metal, the solder feature coupling the device to an interconnect feature extending above the package substrate, wherein the interconnect feature comprises, an inner portion comprising a second metal and an outer portion comprising an intermetallic compound (IMC) of the first and second metals, the IMC between and in contact with the inner portion of the interconnect feature and the solder feature, and between and in contact with the inner portion of the interconnect feature and a dielectric material adjacent to the solder feature.

In second examples, the first example includes wherein the solder feature coupled to the interconnect feature comprises a solder joint structure.

In third examples, for any of examples 1-2 wherein a lateral width of the outer portion comprises about 10 percent to about 20 percent of a lateral width of the inner portion.

In fourth examples, for any of examples 1-3 wherein the outer portion is on sidewalls of the inner portion and on a top portion of the inner portion.

In fifth examples, the fourth example includes wherein the outer portion comprise a liner that surrounds the inner portion above the substrate.

In sixth examples, for any of examples 1-5 wherein the IMC comprises solder materials and copper.

In seventh examples, for any of examples 1-6 wherein an interface between the substrate and the inner portion is free of the IMC.

In eighth examples, for any of examples 1-7 wherein the solder feature comprises one or more of tin, solder, or silver, and the inner portion comprises copper.

In ninth examples, for any of examples 1-8 wherein the solder feature comprises a concave profile, and the interconnect feature comprises a rectangular profile.

In tenth examples, for any of examples 1-9 wherein the dielectric material comprises an underfill material.

In eleventh examples, for any of examples 1-10 wherein the dielectric material comprises an underfill material.

In twelfth examples the second example includes wherein a distance between a first solder joint structure and a second solder joint structure is below about 25 microns.

A thirteenth example is a package structure, comprising a package substrate, a device, and a solder joint between the package structure and the device comprising a first portion comprising a first metal on the device, and a second portion on the first portion comprising, an inner portion comprising a second metal, and an outer portion at least partially surrounding the inner portion, the outer portion comprising an intermetallic compound (IMC) of the first and second metals.

In fourteenth examples, the thirteenth example includes wherein the inner portion is on the substrate and comprises copper, and the first portion comprises a solder material.

In fifteenth examples, for any of examples 13-14 wherein a first portion of the IMC is between and in contact with the inner portion and the first portion, and a second portion of the IMC is between and in contact with the inner portion and an adjacent dielectric material.

In sixteenth examples, for any of examples 13-15 wherein the IMC comprises two or more of copper, tin, or silver.

In seventeenth examples, for any of examples 13-16 wherein the substrate is coupled to a board and the board is coupled to a power supply.

An eighteenth example is a method comprising providing a substrate with a conductive pad on a surface of the substrate nano-roughening the conductive pad, placing a solder pad of a die on the nano-roughened conductive pad and forming an inter metallic compound (IMC) on sidewalls and on a bottom surface of the conductive pad.

In nineteenth examples, the eighteenth example includes wherein providing a substrate with a conductive pad comprises providing an organic substrate with a copper pad.

In twentieth examples, for any of examples 18-19 wherein nano-roughening the conductive pads comprises one or more of sequential bimetallic deposition and chemical etching, or sequential copper oxidation and reduction.

In twenty first examples, for any of examples 18-20 wherein forming the IMC comprises forming an IMC comprising two or more of silver, copper, or tin.

In twenty second examples, for any of examples 18-21 wherein forming the IMC comprises wicking the solder pad on sidewalls and an interface region between the solder pad and the conductive pad.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a package substrate;
a device;
a solder feature comprising a first metal, the solder feature coupling the device to an interconnect feature extending above the package substrate, wherein the interconnect feature comprises:
an inner portion comprising a second metal; and
an outer portion comprising an intermetallic compound (IMC) of the first and second metals, the IMC between and in contact with the inner portion of the interconnect feature and the solder feature, and between and in contact with the inner portion of the interconnect feature and a dielectric material adjacent to the solder feature.

2. The apparatus of claim 1, wherein the solder feature coupled to the interconnect feature comprises a solder joint structure.

3. The apparatus of claim 1, wherein a lateral width of the outer portion comprises about 10 percent to about 20 percent of a lateral width of the inner portion.

4. The apparatus of claim 1, wherein the outer portion is on sidewalls of the inner portion and on a top portion of the inner portion.

5. The apparatus of claim 4, wherein the outer portion comprises a liner that surrounds the inner portion above the substrate.

6. The apparatus of claim 1, wherein the IMC comprises solder materials and copper.

7. The apparatus of claim 1, wherein an interface between the substrate and the inner portion is free of the IMC.

8. The apparatus of claim 1, wherein the solder feature comprises one or more of tin, solder, or silver, and the inner portion comprises copper.

9. The apparatus of claim 1, wherein the solder feature comprises a concave profile, and the interconnect feature comprises a rectangular profile.

10. The apparatus of claim 1, wherein the dielectric material comprises an underfill material.

11. The apparatus of claim 2, wherein the solder joint comprises one of a first level interconnect structure or a second level interconnect structure.

12. The apparatus of claim 2, wherein a distance between a first solder joint structure and a second solder joint structure is below about 25 microns.

13. A package structure, comprising:
a package substrate;
a device; and
a solder joint between the package structure and the device comprising:
a first portion comprising a first metal on the device; and
a second portion on the first portion comprising:
an inner portion comprising a second metal; and
an outer portion at least partially surrounding the inner portion, the outer portion comprising an intermetallic compound (IMC) of the first and second metals.

14. The package structure of claim 13, wherein the inner portion is on the substrate and comprises copper, and the first portion comprises a solder material.

15. The package structure of claim 13, wherein a first portion of the IMC is between and in contact with the inner portion and the first portion, and a second portion of the IMC is between and in contact with the inner portion and an adjacent dielectric material.

16. The package structure of claim 13, wherein the IMC comprises two or more of copper, tin, or silver.

17. The package structure of claim 13, wherein the substrate is coupled to a board and the board is coupled to a power supply.

18. A method, comprising:
providing a substrate with a conductive pad on a surface of the substrate;
nano-roughening the conductive pad;
placing a solder pad of a die on the nano-roughened conductive pad; and
forming an inter metallic compound (IMC) on sidewalls and on a bottom surface of the conductive pad.

19. The method of claim 18, wherein providing a substrate with a conductive pad comprises providing an organic substrate with a copper pad.

20. The method of claim 18, wherein nano-roughening the conductive pads comprises one or more of sequential bimetallic deposition and chemical etching, or sequential copper oxidation and reduction.
